(19) United States
(12) Patent Application Publication
(10) Pub. No.: US 2026/0269817 A1
(43) Pub. Date: Sep. 10, 2026

(54) DYNAMIC DUTY CYCLE MONITOR AND CORRECTION CIRCUIT

(71) Applicant: Apple Inc., Cupertino, CA (US)

(72) Inventors: Yair TALKER, Saratoga, CA (US); Joao Pedro da Silva CERQUEIRA, Santa Clara, CA (US); Mohamed H. ABU-RAHMA, Mountain View, CA (US)

(21) Appl. No.: 19/074,886

(22) Filed: Mar. 10, 2025

(51) Int. Cl. H03K 5/156; H03K 5/00; H03K 5/134

(52) U.S. Cl. CPC H03K 5/1565; H03K 5/134; H03K 2005/00195

(57) ABSTRACT

A duty cycle correction circuit is disclosed. The duty cycle correction circuit includes a delay circuit configured to receive an input clock signal, a first control signal, and a second control signal and control, based on the input clock signal, the first control signal, and the second control signal, respective delays of a rising edge and a falling edge of an output clock signal. The duty cycle correction circuit is configured to adjust a duty cycle of the output clock signal on a cycle-by-cycle basis. The duty cycle correction circuit also includes a time-domain converter circuit configured to generate a comparison signal based on respective durations of a high phase and a low phase of the output clock signal and a decoder circuit configured to generate the first and second control signals using the comparison signal.

### FIELD

The described embodiments relate generally to electronic circuits, and more particularly, to circuits for monitoring clock signals.

### BACKGROUND

Sequential digital circuits utilize clock signals to synchronize operation and the movement of data there between. A clock signal comprises a periodic signal with a high phase and a low phase, and may be further defined by a frequency and a duty cycle. The duty cycle is defined as the amount of time of the active phase of the clock signal (e.g., the high phase) relative to the total cycle period. For example, if during a given clock cycle, the high phase consumes 50% of the time, the duty cycle for that clock signal is said to be 50%. The duty cycle for a given clock signal may be specified to allow various circuits sufficient setup and hold time to facilitate the orderly movement of data.

Due to the importance of a clock signal's duty cycle, many systems utilize duty cycle monitoring circuits. These circuits may sample the high and/or low phase of a given clock signal with another asynchronous clock signal (e.g., using a time-to-digital converter, or TDC). After a statistically significant number of samples has been gathered, the circuit may determine the duty cycle of the clock signal, allowing other circuits to make any necessary corrections thereto.

### BRIEF DESCRIPTION OF THE DRAWINGS

FIG. 1 is a block diagram depicting one embodiment of a duty cycle correction circuit.

FIG. 2 is a schematic diagram depicting one embodiment of a delay circuit used in a duty cycle correction circuit.

FIG. 3 is a schematic diagram illustrating one embodiment of a decoder used in a duty cycle correction circuit.

FIG. 4A is a schematic diagram of a portion of one embodiment of a domino circuit.

FIG. 4B is a diagram further illustrating an embodiment of a domino circuit and related circuitry.

FIG. 5 is a simplified diagram illustrating a test arrangement for a duty cycle correction circuit.

FIG. 6 is a flow diagram illustrating one embodiment of a method for operating a duty cycle correction circuit.

FIG. 7 is a block diagram of an embodiment of a device that includes a duty cycle correction circuit according to the disclosure.

FIG. 8 is a block diagram of various embodiments of computer systems that may include a duty cycle correction circuit according to the disclosure.

FIG. 9 illustrates an example of a non-transitory computer-readable storage medium that stores circuit design information.

### DETAILED DESCRIPTION

Duty cycle monitoring circuits are used to monitor the duty cycle of a clock signal and to perform corrections thereto such that synchronous circuits may function properly.

Due to the importance of a clock signal's duty cycle, many systems utilize duty cycle monitoring circuits. However, currently available duty cycle monitoring circuits sample the high-low phase for a large number of cycles until the number of samples reaches a statistically significant value. This may consume a significant amount of time and allow the clock signal duty cycle to be incorrect for a large number of cycles until corrective actions are taken. Furthermore, current duty cycle monitoring circuits may only monitor the duty cycle when voltage and frequency are stable, but not during sweeps (e.g., during a change from one performance state to another).

The present disclosure is directed to a duty cycle monitoring and correction circuit in which the duty cycle is sampled and corrected on a cycle-by-cycle basis. This may allow better control of the duty cycle and prevent large numbers of clock cycles elapsing with an incorrect duty cycle. The disclosure is further directed to a testing apparatus that includes a domino circuit for verifying the operation of the duty cycle correction circuit.

Various embodiments of a duty cycle correction circuit and testing apparatus are now discussed in further detail below. The discussion is initially embodiments of a duty cycle correction circuit and components thereof. Followed thereafter is a discussion of a domino circuit and testing apparatus for a duty cycle correction circuit. Methods of operation are then described, and the disclosure concludes with descriptions of a devices and systems in which the duty cycle correction circuit may be implemented, as well as a computer-readable medium that may store corresponding design information.

### Duty Cycle Correction Circuit

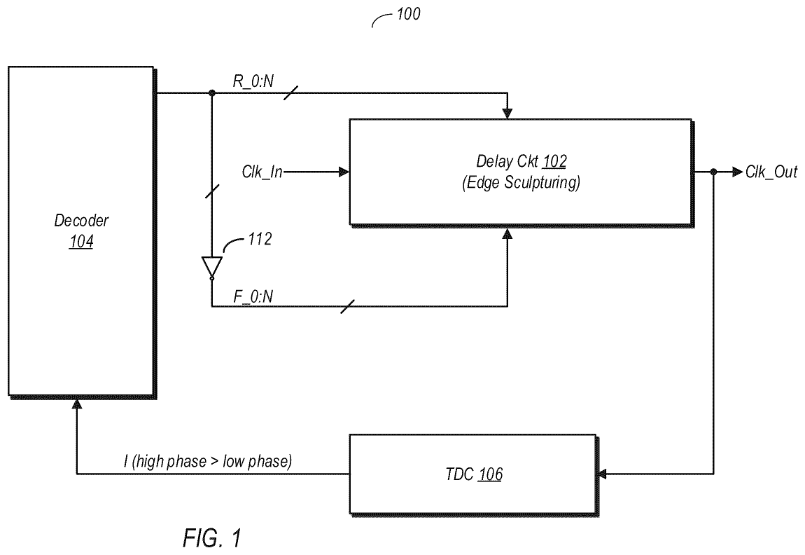

FIG. 1 is a block diagram depicting one embodiment of a duty cycle correction circuit. In the embodiment shown, duty cycle correction circuit 100 includes a delay circuit 102, a decoder 104, and a time domain converter circuit 106. An input clock signal, Clk_In, is received by the delay circuit, with a corresponding output clock signal, Clk_Out, which may be provided to various synchronous circuits downstream.

Delay circuit 102 may also be referred to as an edge sculpturing circuit, as it functions to individually provide delays to the rising and falling edges of the input clock signal. That is delay may be provided to the rising edge of the clock signal independent of the falling edge, and vice versa. In the embodiment shown, delay circuit may receive the input clock signal, a first control signal (R_0:N) and, and a second control signal (F_0:N). In this particular example, the control signals R_0:N and F_0:N are multi-bit control signals, and are complements of one another by virtues of inverters 112 (only one is shown here for the sake of illustration). Using these control signals, delay circuit may control and adjust the respective delays of the rising and falling edges of the input clock signal to generate the output clock signal.

Time domain converter circuit 106 in the embodiment shown is configured to determine a time difference between the rising and falling edges of the input clock signal. In various embodiments, time domain converter 106 may generate, internally, start and stop signals upon detecting clock edges and may use various timing mechanisms, such as counters, to determine the elapsed time between the two clock edges. The elapsed time may be compared to a threshold value to determine whether a particular phase of the clock signal (e.g., the high phase) is longer than the low phase, as is done in this particular embodiment. In response to determining that the high phase has a greater duration than the low phase, the “I” signal is asserted and provided to decoder 106.

It is noted that embodiments of time domain converter 106 that include a register or table for storing different threshold values corresponding to different performance states (which include corresponding different clock frequencies) are possible and contemplated. Furthermore, thresholds may be based on various duty cycles, including but not limited to a 50% duty cycle. Embodiments are further contemplated in which the indications generated by time domain converter 106 may also indicate if the duty cycle of the input clock signal is too high, within some specified limits, or too low.

Decoder 104 in the embodiment shown is configured to, based on the signal output from time domain converter 106, generate the control signals that are used to adjust respective delays applied to the rising and falling edges of the input clock signal in generating the output clock signal. These control signals may thus cause the shifting of the rising and/or falling edges so as to achieve the desired duty cycle of the output clock signals.

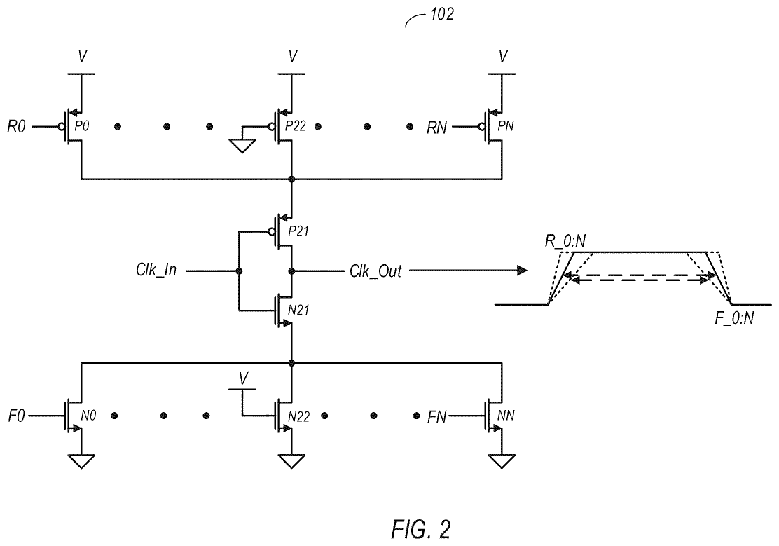

FIG. 2 is a schematic diagram depicting one embodiment of a delay circuit used in a duty cycle correction circuit. In this example, the input clock signal, Clk_In, is provided to an inverter made up of PMOS device P21 and NMOS device N21, which provides on its output the output clock signal, Clk_Out.

The drain terminal of PMOS device P21 in this example is coupled to respective sources terminals of a number of PMOS devices having their respective source terminals hardwired to a voltage source. One of these devices, P22, includes a gate terminal that is hardwired to a ground (or reference) node such that this device remains always on when the circuit is receiving power, and thus a pull-up path can be provided when device P21 is also active. The other PMOS devices are coupled to respective control signals (R0 . . . RN) on their corresponding gate terminals. These devices may be selectively activated or inactivated based on the state of the control signals provided from decoder 104. The selective activation and deactivation of these devices may control the pull-up current when device P21 is active, thereby controlling an amount of delay provided to the input clock signal Clk_In in the generation of the output clock signal, Clk_Out. Generally speaking, higher pull-up currents may reduce the delay applied to the rising edge of the clock signal while lower pull-up current may increase the delay.

Applying delay to the falling edge of the clock signal is carried out using a similar principle in the embodiment shown. The source terminal of NMOS device N21 is coupled to respective drain terminals of devices N0 . . . NN. Device N22 in the example includes a gate terminal that is hardwired to a voltage source such that it remains active whenever power is applied to the circuit and thus provides a pull-down path when N21 is also active. The other NMOS devices shown here have respective gate terminals coupled to receive a corresponding one of the control signals F0 . . . FN. Selective activation and de-activation of these devices may be used to control the amount of pull-down current when N21 is active, and thus adjust the delay applied to the input clock signal in the generation of the output signal. Higher amounts of pull-down current may correspond to lower values of delay, while lower values of pull-down current may correspond to higher values of delay.

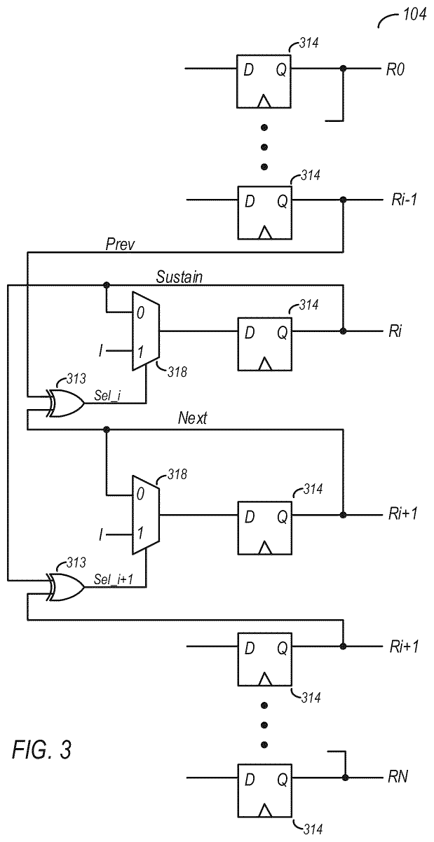

FIG. 3 is a schematic diagram illustrating one embodiment of a decoder used in a duty cycle correction circuit. In the embodiment shown, decoder 104 includes a plurality of flip-flop circuits 314 configured to output corresponding ones of a plurality of control signals. For the sake of illustrations, only two of the flip-flop circuits 314 in this example are shown having circuitry coupled to their respective inputs, although it is to be understood that similar circuits are provided on the inputs of others one of the flip-flop circuits. As shown here, the circuitry on the inputs includes an exclusive OR (XOR) gate 313 and a selection circuit 318.

In the example shown, for a given cycle of the output clock signal, decoder 104 may shift bits in a first direction (e.g., upward, as shown on the page), a second direction (e.g., downward as shown on the page), or maintain the current state of the control signals. When initialized, the values of R0 . . . Ri may be logic 0's (provided to respective gate terminals of the PMOS devices of a delay circuit such as that shown in FIG. 2), while the values of Ri+1 . . . RN are logic 1's (provided to respective gate terminals of the PMOS devices of a delay circuit such as that shown in FIG. 2). Depending on the state of the output signal I from the time domain converter 106 the state of the signal Prev (propagated to one of the XOR gates 313, and the state of Next signal (received as true one of the XOR gates 313 and as a complement in the other shown here), the Sel_i and Sel_i+1 signals may be asserted to the selection inputs of selection circuits 318. The selection circuits 318 shown here either output the value I (output from the time domain converter 106) or a values that is fed back to the input of the correspondingly coupled flip-flop circuit 314. At any given point in time, only two of the selection circuits will have a select value set to ‘1’, and effectively intercept the value denoted by the input bit I. For example, if R0 to Ri are logic 0's and Ri+1 to RN are logic 1's, then only Ri and Ri+1 logic gates will result in a select input of 1 to correspondingly coupled selection circuit 318. The remainder of the multiplexer circuits on the inputs of the other flip-flop circuits 314 will remain as logic 0's, since their respective XOR gates will have two 0's or two 1's as logic values for inputs. Thus the outputs of their respectively coupled flip-flop circuits 314 will sustain their previous state. If the value of I is a logic 0, the flip-flop circuit 314 with the output Ri sustains its previous value and that with Ri+1 as its output will flip the next cycle, and the focus of determining the direction of the movement of 1's and 0's (output from the various flip-flop circuits 314) would shift to the flip-flop circuits 314 having Ri+1 and Ri+2 as their respective outputs. Similarly, if the value of I is a logic 1, in the next cycle the focus of determining the direction of movement of 1's and 0's would shift to the flip-flop circuits 314 having Ri and Ri−1 as their respective outputs.

The generated control signals may, when there are more logic 0's than logic 1's, cause a reduction the delay provided to the rising edge of the input clock signal by delay circuit 102 relative to the falling edge, thereby increasing the duty cycle. When decoder generates more logic 1's than 0's, the delay applied to the falling edge of the input clock signal may be reduced relative to the rising edge, thereby reducing the duty cycle. Since the time domain converter 106 is capable of detecting the rising and falling edges of every clock cycle (and thus measuring the duty cycle), the duty cycle may be adjusted on a cycle-by-cycle basis, without any need to wait for a statistically significant number of samples of the clock signal.

### Test Apparatus

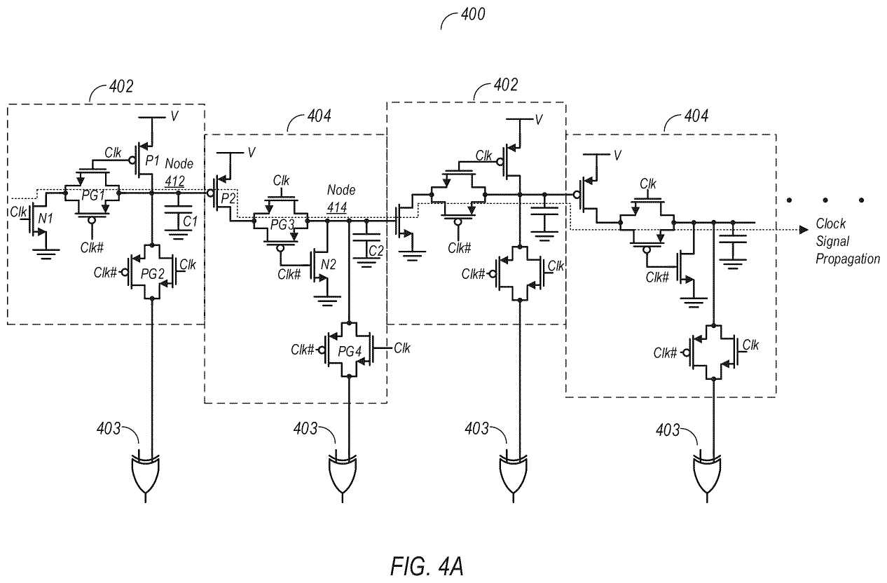

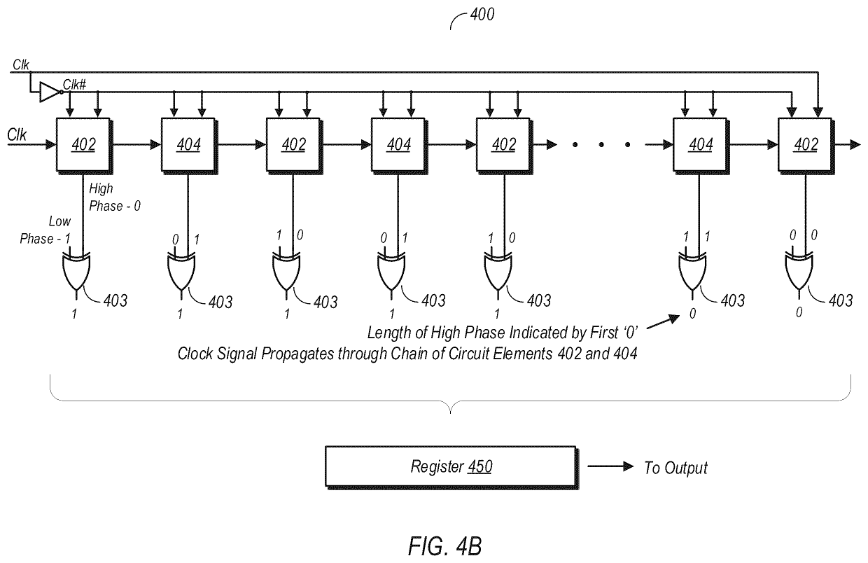

FIG. 4A is a schematic diagram of a portion of one embodiment of a domino circuit. In the embodiment shown, domino circuit 400 may be used as part of a test apparatus to measure the effectiveness of the duty cycle correction circuit.

Domino circuit 400 a shown here includes a number of circuit elements 402 and 404, which are arranged in an alternating, series-couple pattern. Circuit element 402 includes an NMOS device N1, which is responsive to a high phase of the clock signal and, when activated, forms a pull-down path between node 412 and ground (through passgate PG1). The value on this node may also be passed through passgate PG2 to one of the inputs of exclusive-OR gate 403. When the clock signal is low, both PG1 and PG2 are in a high-impedance state, and no signal propagates through either. However, when the clock signal is low, PMOS device P1 is activated, thereby forming a pull-up circuit between node 412 and the supply voltage node V, thus making P1 function as a precharge circuit.

The low on node 412, when the clock signal is high, is also propagated to PMOS device P2 of circuit element 404. When active, PMOS device P2 forms a pull-up path is formed between node 414, through passgate PG3 to the supply voltage node V. At this time, passgate PG4 is also transparent, and thus the high on node 414 is passed to one of the inputs of the correspondingly coupled exclusive-OR gate 403. The high on node 414 also propagates to the NMOS input device of the next instance of circuit element 402.

When the clock signal is low, both passgates PG3 and PG4 are in a high-impedance state and thus block signal propagation that would otherwise pass through. Furthermore, the low on the clock signal results in a high on its complement, Clk #, which activates NMOS device N2. As a result, when active, NMOS device N2 acts as a pre-discharge circuit and pulls node 414 low.

Signal propagation of the high phase of the clock signal proceeds as described above, passing from one circuit element 402/404 to the next circuit element 402/404 in the series-coupled chain. The length of the series-coupled chain through which the high phase of the clock signal propagates may be indicated by the outputs of the exclusive OR-gates 403 as shown in the drawing, and may thus be used to determine both the length of the high portion of the clock signal as well as whether or not the duty cycle correction circuit 100 is performing as desired.

FIG. 4B is a diagram further illustrating an embodiment of a domino circuit and related circuitry. In the example shown, domino circuit 400 includes a plurality of circuit elements 402 and 404, which are coupled in an alternating, series fashion. Each of the circuit elements 402 and 404 is coupled to receive the clock signal, Clk, and its complement, Clk #. As with the embodiment of FIG. 4A, each of the circuit elements 402 and 404 include one circuit node coupled to an input of an exclusive OR-gate 403. During testing, alternating ones of the exclusive OR-gates 403 have a logic 1 or a logic 0 provided to their other inputs, in an alternating pattern that matches that of the arrangement of circuit elements 402 and 404. As the high phase of the clock signal propagates through the series-coupled chain of circuit elements 402 and 404, each of the exclusive OR-gates 403 outputs a value. This will begin with each exclusive-OR gate 403 outputting a logic 1. The length of the high phase of the clock signal can be determined based on the first exclusive-OR gate 403 that outputs a logic 0. The logic values output from each of the exclusive OR-gates 402 may be captured by a register 450 that outputs the value to another location where the results of the test may be observed.

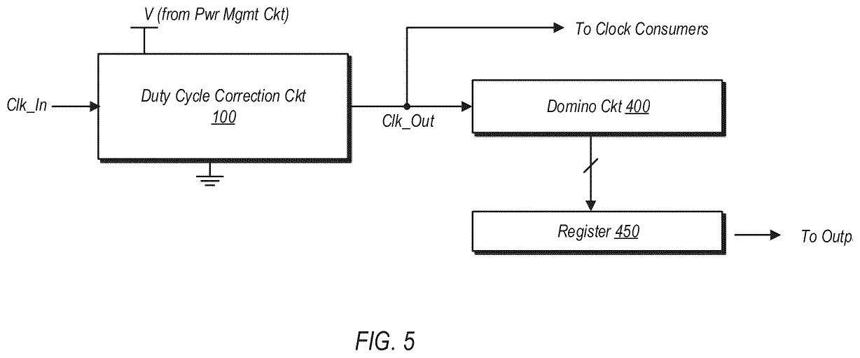

FIG. 5 is a simplified diagram illustrating a test arrangement for a duty cycle correction circuit. In the illustrated example, a domino circuit 400 is coupled to an output of a duty cycle correction circuit, and is thus arranged to measure the duty cycle of the output clock signal, Clk_Out. In accordance with the discussion above, register 450 may capture a digital value indicative of the duration of the high phase of the output clock circuit. This value may be output to another location for observation, where the effectiveness of the duty cycle correction circuit 100 may be determined.

One application of testing per the disclosure is during performance state changes in an integrated circuit in which duty cycle correction circuit is implemented. When a performance state changes, the frequency of the input clock signal as well as the supply voltage may change. This in turn can affect propagation delays, including those that have an impact on the duty cycle of the clock signal, particularly when the voltage is changed. Accordingly, one application of the test apparatus as shown here is to determine the effectiveness of the duty cycle correction circuit during voltage changes.

It is noted that while the circuits discussed above have been implemented using various types of NMOS and PMOS transistors, the disclosure is not intended to limit embodiments falling within its scope to these types of devices. Accordingly, in addition to the various types of devices discussed elsewhere herein, the present disclosure also contemplates embodiments that, e.g., use non-planar devices such as FinFETs, GAAFETs (Gate All Around FETs) and other types. Embodiments implemented using various types of bipolar devices are also possible and contemplated. The disclosure further contemplates the use of materials, technologies and devices that are speculative or not widely used as of this writing. These materials include graphene, carbon nanotubes, gallium arsenide, gallium nitride, silicon carbide, and so on, as well as devices and circuits implemented using these materials. The use of memristors in various circuit structures is also possible and contemplated.

### Method of Operating

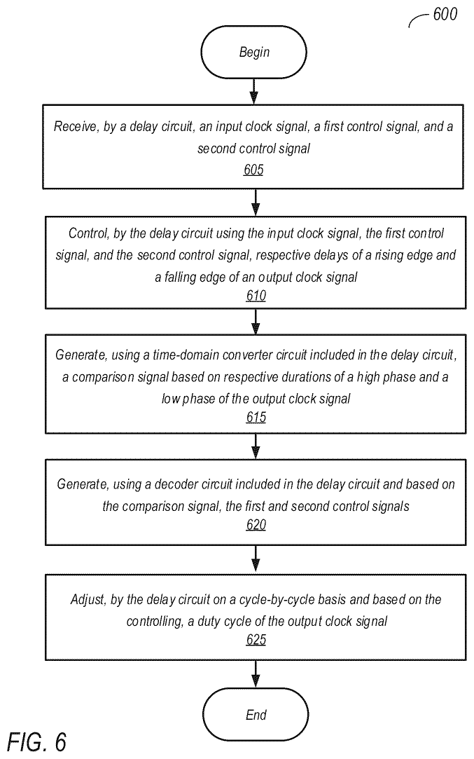

FIG. 6 is a flow diagram illustrating one embodiment of a method for operating a duty cycle correction circuit. Method 600 may be carried out using various embodiments of the circuits discussed above. Circuit embodiments capable of carrying out Method 600, but not otherwise discussed herein, are also considered to fall within the scope of this disclosure.

Method 600 includes receiving, by a delay circuit, an input clock signal, a first control signal, and a second control signal (block 605). The method further includes controlling, by the delay circuit using the input clock signal, the first control signal, and the second control signal, respective delays of a rising edge and a falling edge of an output clock signal (block 610) and generating, using a time-domain converter circuit included in the delay circuit, a comparison signal based on a duration of a first phase of the output clock signal (block 615). The method further includes generating, using a decoder circuit included in the delay circuit and based on the comparison signal, the first and second control signals (block 620) and adjusting, by the delay circuit on a cycle-by-cycle basis and based on the controlling, a duty cycle of the output clock signal, wherein adjusting the duty cycle comprises applying a first delay to a rising edge of the clock signal and a second delay to a falling edge of the clock signal (block 625).

In some embodiments, the method includes measuring, using a domino circuit, a duration of the first phase of the output clock signal. When the frequency and duration of the first phase of the output clock signal are known, the duty cycle can be determined. Such embodiments further includes storing, in a register coupled to the domino circuit, a value indicative of respective durations of the high phase and the low phase.

The domino circuit that carries out a portion of the method includes a plurality of circuit elements including a first subset of circuit elements and a second subset of circuit elements. Accordingly, the method includes precharging, using a precharge circuit and during a second phase of the clock signal, a first node in ones of the first subset of circuit elements and pre-discharging, using a pre-discharge during a second phase of the output clock signal, a second node in ones of the second subset of circuit elements. The method also includes propagating, during a first phase of the output clock signal and through passgate circuits of ones of the first subset of circuit elements and ones of the second subset of circuit elements, the high phase of the clock signal. These method embodiments also include inhibiting propagation of the output clock signal, using passgate circuits of the ones of the first subset of circuit elements and the ones of the second subset of circuit elements, the high phase of the clock signal during the second phase of the clock signal.

In various embodiments, the method includes generating, using a first plurality of flip-flop circuits of the decoder circuit, the first control signal based on a measurement of first phase of the clock signal and generating, using a second plurality of flip-flop circuits of the decoder circuit, the second control signal based on the measurement of first phase of the clock signal. These embodiments may further includes changing, using the decoder circuit, respective states of the first control signal and the second control signal in response to a determination that the comparison signal indicates that the first duration of the first phase of the output clock signal is greater than a second duration of a second phase of the output clock signal. Embodiments of the method may further include adjusting, using a plurality of pull-up circuits of the delay circuit, the first delay to the input clock signal, wherein adjusting the first delay comprises adjusting a pull-up current drawn by the plurality of pull-up circuits, and adjusting, using a plurality of pull-down circuits of the delay circuit, the second delay of the input clock signal, wherein adjusting the second delay applied comprises adjusting a pull-down current drawn by the plurality of pull-down circuits.

### Device, System, and Computer-readable Medium Embodiments

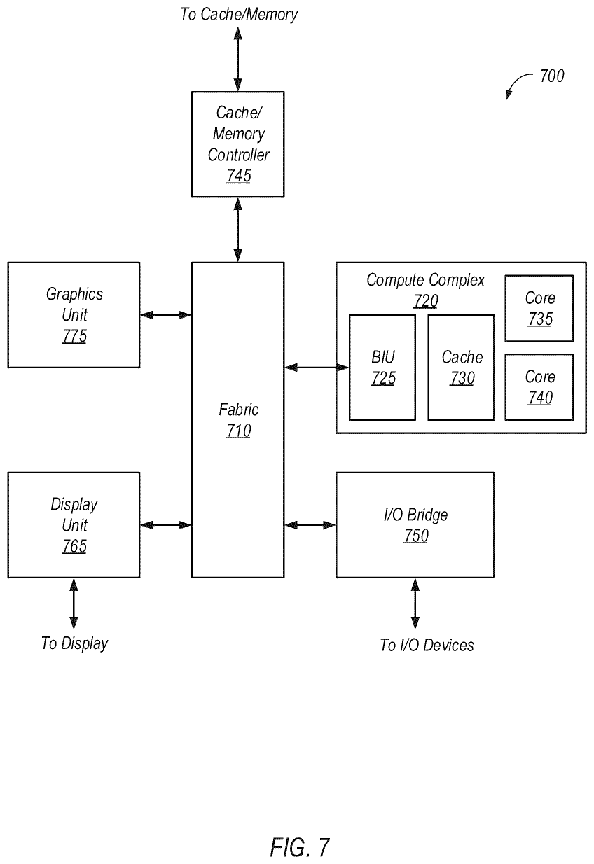

Referring now to FIG. 7, a block diagram illustrating an example embodiment of a device that may include a duty cycle correction circuit and corresponding test apparatus is shown. In various embodiments, device 700 may implement functionality of delay-line circuit 100 as depicted in FIG. 1. In some embodiments, elements of device 700 may be included within a system on a chip. In some embodiments, device 700 may be included in a mobile device, which may be battery-powered. Therefore, power consumption by device 700 may be an important design consideration. In the illustrated embodiment, device 700 includes fabric 710, compute complex 720, input/output (I/O) bridge 750, cache/memory controller 745, graphics unit 775, and display unit 765. In some embodiments, device 700 may include other components (not shown) in addition to, or in place of, the illustrated components, such as video processor encoders and decoders, image processing or recognition elements, computer vision elements, etc.

Fabric 710 may include various interconnects, buses, MUX's, controllers, etc., and may be configured to facilitate communication between various elements of device 700. In some embodiments, portions of fabric 710 may be configured to implement various different communication protocols. In other embodiments, fabric 710 may implement a single communication protocol, and elements coupled to fabric 710 may convert from the single communication protocol to other communication protocols internally.

In the illustrated embodiment, compute complex 720 includes bus interface unit (BIU) 725, cache 730, and cores 735 and 740. In various embodiments, compute complex 720 may include various numbers of processors, processor cores, and caches. For example, compute complex 720 may include 1, 2, or 4 processor cores, or any other suitable number. In one embodiment, cache 730 is a set associative L2 cache. In some embodiments, cores 735 and 740 may include internal instruction and data caches. In some embodiments, a coherency unit (not shown) in fabric 710, cache 730, or elsewhere in device 700, may be configured to maintain coherency between various caches of device 700. BIU 725 may be configured to manage communication between compute complex 720 and other elements of device 700. Processor cores, such as cores 735 and 740, may be configured to execute instructions of a particular instruction set architecture (ISA) which may include operating system instructions and user application instructions. These instructions may be stored in a computer readable medium such as a memory coupled to cache memory controller 745 as discussed below.

As used herein, the term “coupled to” may indicate one or more connections between elements, and a coupling may include intervening elements. For example, in FIG. 7, graphics unit 775 may be described as “coupled to” a memory through fabric 710 and cache/memory controller 745. In contrast, in the illustrated embodiment of FIG. 7, graphics unit 775 is “directly coupled” to fabric 710 because there are no intervening elements.

Cache/memory controller 745 may be configured to manage transfer of data between fabric 710 and one or more caches and memories. For example, cache/memory controller 745 may be coupled to an L3 cache, which may, in turn, be coupled to a system memory. In other embodiments, cache/memory controller 745 may be directly coupled to a memory. In some embodiments, cache/memory controller 745 may include one or more internal caches. Memory coupled to cache/memory controller 745 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 745 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 720 to cause the computing device to perform functionality described herein.

Graphics unit 775 may include one or more processors, e.g., one or more graphics processing units (GPUs). Graphics unit 775 may receive graphics-oriented instructions, such as OPENGL®, Metal®, or DIRECT3D® instructions, for example. Graphics unit 775 may execute specialized GPU instructions or perform other operations based on the received graphics-oriented instructions. Graphics unit 775 may generally be configured to process large blocks of data in parallel, and may build images in a frame buffer for output to a display, which may be included in the device or may be a separate device. Graphics unit 775 may include transform, lighting, triangle, and rendering engines in one or more graphics processing pipelines. Graphics unit 775 may output pixel information for display images. Graphics unit 775, in various embodiments, may include programmable shader circuitry which may include highly parallel execution cores configured to execute graphics programs, which may include pixel tasks, vertex tasks, and compute tasks (which may or may not be graphics-related).

Display unit 765 may be configured to read data from a frame buffer and provide a stream of pixel values for display. Display unit 765 may be configured as a display pipeline in some embodiments. Additionally, display unit 765 may be configured to blend multiple frames to produce an output frame. Further, display unit 765 may include one or more interfaces (e.g., MIPI® or embedded display port (eDP)) for coupling to a user display (e.g., a touchscreen or an external display).

I/O bridge 750 may include various elements configured to implement universal serial bus (USB) communications, security, audio, and low-power always-on functionality, for example. I/O bridge 750 may also include interfaces such as pulse-width modulation (PWM), general-purpose input/output (GPIO), serial peripheral interface (SPI), and inter-integrated circuit (I2C), for example. Various types of peripherals and devices may be coupled to device 700 via I/O bridge 850.

In some embodiments, device 700 includes network interface circuitry (not explicitly shown), which may be connected to fabric 710 or I/O bridge 750. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 700 with connectivity to various types of other devices and networks.

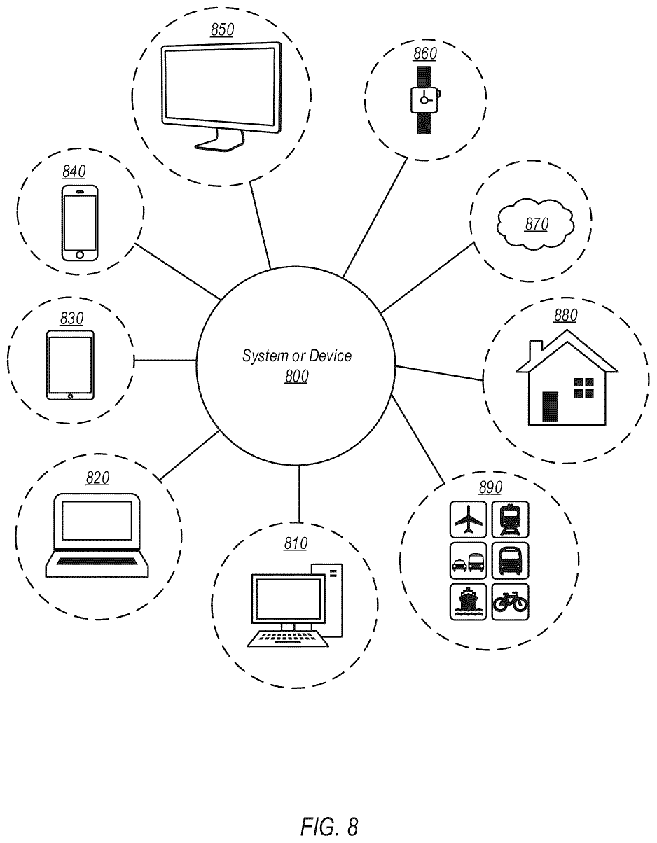

Turning now to FIG. 8, various types of systems that may include any of the circuits, devices, or systems discussed above are illustrated. System or device 800, which may incorporate or otherwise utilize one or more of the techniques described herein, may be utilized in a wide range of areas. For example, system or device 800 may be utilized as part of the hardware of systems such as a desktop computer 810, laptop computer 820, tablet computer 830, cellular or mobile phone 840, or television 850 (or set-top box coupled to a television).

Similarly, disclosed elements may be utilized in a wearable device 860, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 800 may also be used in various other contexts. For example, system or device 800 may be utilized in the context of a server computer system, such as a dedicated server or on shared hardware that implements a cloud-based service 870. Still further, system or device 800 may be implemented in a wide range of specialized everyday devices, including devices 880 commonly found in the home such as refrigerators, thermostats, security cameras, etc. The interconnection of such devices is often referred to as the “Internet of Things” (IoT). Elements may also be implemented in various modes of transportation. For example, system or device 800 could be employed in the control systems, guidance systems, entertainment systems, etc. of various types of vehicles 890.

The applications illustrated in FIG. 8 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

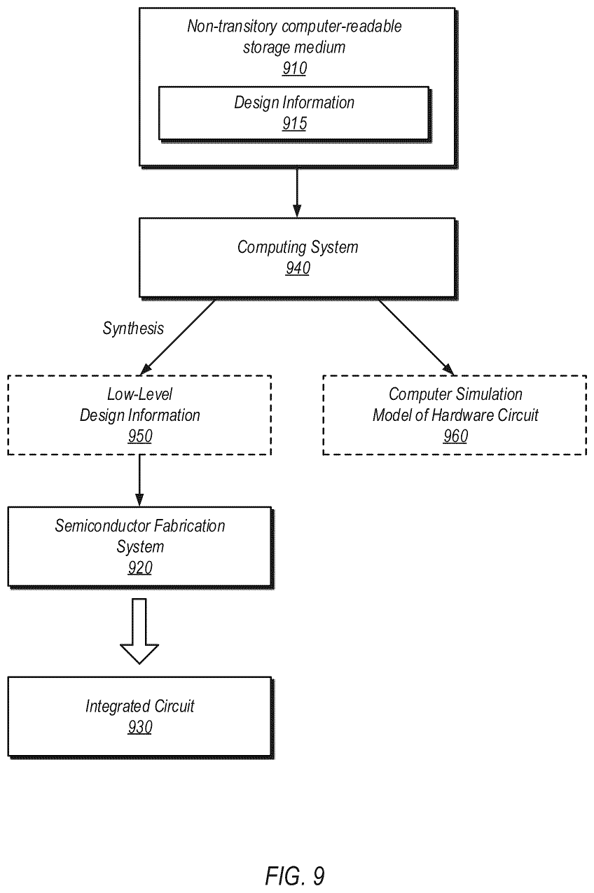

FIG. 9 is a block diagram illustrating an example of a non-transitory computer-readable storage medium that stores design information 915, according to some embodiments. In the illustrated embodiment, computing system 940 is configured to process design information 915. This may include executing instructions included in design information 915, interpreting instructions included in design information 915, compiling, transforming, or otherwise updating design information 915, etc. Therefore, design information 915 controls computing system 940 (e.g., by programming computing system 940) to perform various operations discussed below, in some embodiments.

In the illustrated example, computing system 940 processes design information 915 to generate both computer simulation model of hardware circuit 960 and low-level design information 950. In other embodiments, computing system 940 may generate only one of these outputs, may generate other outputs based on design information 915, or both. Regarding computer simulation model of hardware circuit 960, computing system 940 may execute instructions of a hardware description language that includes register transfer level (RTL) code, behavioral code, structural code, or some combination thereof. The simulation model may perform the functionality specified by design information 915, facilitate verification of the functional correctness of the hardware design, generate power consumption estimates, generate timing estimates, etc.

In the illustrated example, computing system 940 also processes design information 915 to generate low-level design information 950 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 950 (potentially among other inputs), semiconductor fabrication system 920 is configured to fabricate integrated circuit 930 (which may correspond to functionality of the computer simulation model of hardware circuit 960). Note that computing system 940 may generate different simulation models based on design information at various levels of description, including low-level design information 950, design information 915, and so on. The data representing low-level design information 950 and computer simulation model of hardware circuit 960 may be stored on non-transitory computer-readable storage medium 910, or on one or more other media.

In some embodiments, low-level design information 950 controls (e.g., programs) semiconductor fabrication system 920 to fabricate integrated circuit 930. Thus, when processed by the fabrication system, the design information may program the fabrication system to fabricate a circuit that includes various circuitry disclosed herein.

Non-transitory computer-readable storage medium 910 may comprise any of various appropriate types of memory devices or storage devices. Non-transitory computer-readable storage medium 910 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash memory, magnetic media, e.g., a hard drive, or optical storage; registers, or other similar types of memory elements, etc. Non-transitory computer-readable storage medium 910 may include other types of non-transitory memory as well, or combinations thereof. Accordingly, non-transitory computer-readable storage medium 910 may include two or more memory media, which may reside in different locations for example, in different computer systems that are connected over a network.

Design information 915 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 940, semiconductor fabrication system 920, or both. In some embodiments, design information 915 may also include one or more cell libraries that specify the synthesis, layout, or both of integrated circuit 930. In some embodiments, design information 915 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 930 may, in various embodiments, include one or more custom macrocells, such as memories, analog or mixed-signal circuits, and the like. In such cases, design information 915 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 920 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 920 may also be configured to perform various testing of fabricated circuits for correct operation.

In various embodiments, integrated circuit 930 and computer simulation model of hardware circuit 960 are configured to operate according to a circuit design specified by design information 915, which may include performing any of the functionality described herein. For example, integrated circuit 930 may include any of various elements shown in FIGS. 1-5 and 7. Further, integrated circuit 930 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 915. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 915 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 950. Low-level design information 950 may program semiconductor fabrication system 920 to fabricate integrated circuit 930.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a duty cycle correction circuit that includes:
a delay circuit configured to:
receive an input clock signal, a first control signal, and a second control signal;
control, based on the input clock signal, the first control signal, and the second control signal, respective delays of a rising edge and a falling edge of an output clock signal; and
adjust a duty cycle of the output clock signal on a cycle-by-cycle basis;
a time-domain converter circuit configured to generate a comparison signal based on a duration of a first phase of the output clock signal; and
a decoder circuit configured to generate the first and second control signals using the comparison signal.

2. The apparatus of claim 1, further comprising a domino circuit configured to measure a duration of the first phase of the output clock signal.

3. The apparatus of claim 2, further comprising a register coupled to the domino circuit and configured to store a value indicative of respective durations of the first phase of the output clock signal.

4. The apparatus of claim 2, wherein the domino circuit includes:
a plurality of passgates including a first subset of passgates and a second subset of passgates;
a plurality of precharge circuits, wherein ones of the plurality of precharge circuits are coupled to corresponding ones of the first subset of passgates; and
a plurality of pre-discharge circuits, wherein ones of the plurality of pre-discharge circuits are coupled to corresponding ones of the second subset of passgates.

5. The apparatus of claim 4, wherein, during a first phase of the output clock signal:
ones of the plurality of passgates are configured to block propagation of the output clock signal;
ones of the plurality of precharge circuits are configured to precharge a correspondingly coupled ones of a first plurality of signal nodes; and
ones of the plurality of pre-discharge circuits are configured to discharge correspondingly coupled ones of a second plurality of signal node; and
wherein, during a second phase of the output clock signal:
ones of the plurality of passgates are configured to allow propagation of the of the output clock signal; and
ones of the plurality of precharge circuits and ones of the plurality of pre-discharge circuits are inactive.

6. The apparatus of claim 1, wherein the decoder circuit includes:
a first plurality of flip-flop circuits configured to generate the first control signal, the first control signal comprising a first plurality of bits based on a previous state of the first control signal and a measurement of a duration of the first phase of the output clock signal; and
a second plurality of flip-flop circuits configured to generate the second control signal, the second control signal comprising a second plurality of bits based on a previous state of the first control signal and a measurement of a first duration of the first phase of the output clock signal.

7. The apparatus of claim 6, wherein the decoder circuit is further configured to change respective states of the first control signal and the second control signal in response to a determination that the comparison signal indicates that the duration of the first phase of the output clock signal is greater than a duration of a second phase of the output clock signal.

8. The apparatus of claim 6, wherein the delay circuit includes:
a plurality of pull-up circuits coupled to receive corresponding ones of the first plurality of bits, wherein the plurality of pull-up circuits are configured control a delay of the rising edge of the output clock signal based on respective states of ones of the first plurality of bits, wherein, to control the delay of the rising edge of the output clock signal, ones of the plurality of pull-up circuits are configured to source current to an output clock signal node; and
a plurality of pull-down circuits coupled to receive corresponding ones of the second plurality of bits; wherein the plurality of pull-down circuits are configured to control a delay of the falling edge of the output clock signal based on respective states of ones of the second plurality of bits, wherein, to control the delay of the falling edge of the output clock signal, ones of the plurality of pull-down circuits are configured to sink current from the output clock signal node.

9. A method comprising:
receiving, by a delay circuit, an input clock signal, a first control signal, and a second control signal;
controlling, by the delay circuit using the input clock signal, the first control signal, and the second control signal, respective delays of a rising edge and a falling edge of an output clock signal;
generating, using a time-domain converter circuit included in the delay circuit, a comparison signal based on a duration of a first phase of the output clock signal;
generating, using a decoder circuit included in the delay circuit and based on the comparison signal, the first and second control signals; and
adjusting, by the delay circuit on a cycle-by-cycle basis and based on the controlling, a duty cycle of the output clock signal, wherein adjusting the duty cycle comprises applying a first delay to a rising edge of the output clock signal and a second delay to a falling edge of the output clock signal.

10. The method of claim 9, further comprising measuring, using a domino circuit, a duration of the first phase of the output clock signal.

11. The method of claim 10, further comprising storing, in a register coupled to the domino circuit, a value indicative of duration of the first phase of the output clock signal.

12. The method of claim 10, wherein the domino circuit includes a plurality of circuit elements including a first subset of circuit elements and a second subset of circuit elements, and wherein the method further comprises:
precharging, using a precharge circuit and during a low phase of the output clock signal, a first node in ones of the first subset of circuit elements;
pre-discharging, using a pre-discharge during a low phase of the output clock signal, a second node in ones of the second subset of circuit elements; and
propagating, during a high phase of the output clock signal and through passgate circuits of ones of the first subset of circuit elements and ones of the second subset of circuit elements, the high phase of the output clock signal.

13. The method of claim 12, further comprising:
inhibiting propagation of the output clock signal, using passgate circuits of the ones of the first subset of circuit elements and the ones of the second subset of circuit elements, the high phase of the output clock signal during the low phase of the output clock signal.

14. The method of claim 9, further comprising:
generating, using a first plurality of flip-flop circuits of the decoder circuit, the first control signal based on a measurement of first phase of the output clock signal; and
generating, using a second plurality of flip-flop circuits of the decoder circuit, the second control signal based on the measurement of first phase of the output clock signal.

15. The method of claim 14, further comprising changing, using the decoder circuit, respective states of the first control signal and the second control signal in response to a determination that the comparison signal indicates that the duration of the first phase of the output clock signal is greater than a duration of a second phase of the output clock signal.

16. The method of claim 14, further comprising:
adjusting, using a plurality of pull-up circuits of the delay circuit, the first delay to the input clock signal, wherein adjusting the first delay comprises adjusting a pull-up current drawn by the plurality of pull-up circuits; and
adjusting, using a plurality of pull-down circuits of the delay circuit, the second delay of the input clock signal, wherein adjusting the second delay applied comprises adjusting a pull-down current drawn by the plurality of pull-down circuits.

17. A system comprising:
a duty cycle correction circuit that includes:
a delay circuit configured to:
receive an input clock signal, a first control signal, and a second control signal;
control, based on the input clock signal, the first control signal, and the second control signal, respective delays of a rising edge and a falling edge of an output clock signal generated based on the input clock signal; and
adjust a duty cycle of the output clock signal on a cycle-by-cycle basis;
a time-domain converter circuit configured to generate a comparison signal based on a high phase of the output clock signal; and
a decoder circuit configured to generate the first and second control signals using the comparison signal; and
a test circuit coupled to receive the output clock signal, wherein the test circuit includes:
a domino circuit configured to measure a duration of the high phase of the output clock signal; and
a register configured to store a measurement value corresponding to the duration of the high phase of the output clock signal.

18. The system of claim 17, wherein the domino circuit includes;
a plurality of passgates including a first subset of passgates and a second subset of passgates wherein ones of the first subset of passgates are configured to propagate the output clock signal during the high phase of the output clock signal, and further configured to inhibit propagation of the output clock signal during a low phase of the output clock signal;
a plurality of precharge circuits, wherein ones of the plurality of precharge circuits are coupled to corresponding ones of the first subset of passgates and configured to precharge a correspondingly coupled first circuit node during the low phase of the output clock signal; and
a plurality of pre-discharge circuits, wherein ones of the plurality of pre-discharge circuits are coupled to corresponding ones of the second subset of passgates and configured to precharge a correspondingly coupled second node during the low phase of the output clock signal.

19. The system of claim 18, further comprising a plurality of logic gates coupled between ones of the second subset of passgates and the register, wherein the plurality of logic gates are configured to generate the measurement value.

20. The system of claim 18, wherein the delay circuit includes:
a plurality of pull-up circuits, wherein the plurality of pull-up circuits are configured control a delay of the rising edge of the output clock signal based on respective states of ones of a first plurality of bits comprising the first control signal, wherein, to control the delay of the rising edge of the output clock signal, ones of the plurality of pull-up circuits are configured to source current to an output clock signal node; and
a plurality of pull-down circuits, wherein the plurality of pull-down circuits are configured to control a delay of the falling edge of the output clock signal based on respective states of ones of a second plurality of bits comprising the second control signal, wherein, to control the delay of the falling edge of the output clock signal, ones of the plurality of pull-down circuits are configured to sink current from the output clock signal node.
